(19) United States
(12) Patent Application Publication
(10) Pub. No.: US 2026/0090421 A1
(43) Pub. Date: Mar. 26, 2026

(54) COMPOSITE SUBSTRATE, SEMICONDUCTOR DEVICE USING THE SAME AND MANUFACTURING METHOD THEREOF

(71) Applicants: nD-HI Technologies Lab, Inc., Taipei City (TW); ETRON TECHNOLOGY, INC., Hsinchu (TW)

(72) Inventors: Ho-Ming TONG, Taipei City (TW); Chao-Chun LU, Hsinchu (TW)

(73) Assignees: nD-HI Technologies Lab, Inc., Taipei City (TW); ETRON TECHNOLOGY, INC., Hsinchu (TW)

(21) Appl. No.: 19/332,267

(22) Filed: Sep. 18, 2025

Related U.S. Application Data
(60) Provisional application No. 63/696,859, filed on Sep. 20, 2024.
(60) Provisional application No. 63/718,093, filed on Nov. 8, 2024.

(51) Int. Cl. H01L 23/538; H01L 21/48; H01L 23/00; H01L 23/15; H01L 23/373; H01L 25/18; H10B 80/00; H10D 80/30

(52) U.S. Cl. CPC H10W 70/65; H10W 40/254; H10W 70/095; H10W 70/611; H10W 90/401; H10B 80/00; H10D 80/30; H10W 70/692; H10W 90/00; H10W 90/724

(57) ABSTRACT

A composite substrate containing thermally conductive materials is provided. The composite substrate includes a glass base, a first RDL, a second RDL and a thermal dissipation layer. The glass base has a first surface, a second surface opposite to the first surface and a through glass via (TGV) extending to the second surface from the first surface. The first RDL is disposed adjacent to the first surface of the glass base or the thermal dissipation layer. The second RDL is disposed adjacent to the second surface of the glass base. The thermal dissipation layer is disposed on the glass base, having a through thermal via (TTV) extending to the TGV.

This application claims the benefit of US provisional application Ser. No. 63/696,859, filed Sep. 20, 2024, the subject matter of which is incorporated herein by reference, and claims the benefit of US provisional application Ser. No. 63/718,093, filed Nov. 8, 2024, the subject matter of which is incorporated herein by reference.

### BACKGROUND

### Technical Field

The disclosure relates in general to a composite substrate, a semiconductor device using the same and a manufacturing method thereof.

### Description of the Related Art

5G/6G and astonishing AI advancements will enable endless applications from data center to edge devices, leading to an explosive growth in data traffic from 120 zettabytes in 2023 to 200 zettabytes by 2030, and AI economy from US$189 billion in 2023 to US$4.8 trillion by 2030, as well as AI chips covering extreme advanced processors (e.g., general-purpose GPUs and custom ASICs), extreme advanced memories (e.g., HBMs) and extreme advanced packaging, (notably 2.5D ICs) for high-performance data processing.

To process the skyrocketing data traffic at data centers (the largest AI growth engine), extreme 2.5D packages containing extreme GPUs (with a power as high as 1,200 W/GPU now and higher in the future) and extreme HBMs have successfully been and will continue to be implemented, which, however, are continuously falling short of achieving the ever-greater computational power requirement at 2×performance/2 months per GPU computing (as opposed to 2×performance/18 months per conventional CPU computing which had been governing the semiconductor industry for decades) required by accelerating AI adoption.

To rapidly elevate compute power using available extreme 2.5D or future 3D technologies, escalating AI compute requirements demand fast migration to ever-large packages based on ever-larger, new, more functional (e.g., embedded and heterogeneous) interposers and substrates (which are approaching wafer-scale and can soon go beyond wafer scale), and accordingly panel-level packaging (PLP) to accommodate ever-more compute dies (e.g., GPUs or ASICs), ever-more memory dies (e.g., HBMs) and ever more die-to-die interconnects. Not only are the interposers, substrates and related advanced packages getting bigger, ICs are also getting bigger. A case in point is Cerebras's wafer-scale engine or system-on-chip (SoC), reaching an astounding size of 215 mm×215 mm and requiring a power as large as 15K W/chip.

Bonding of two larger electronic components with distinctly different coefficients of thermal expansion (CTEs) such as in the bonding of (a) a larger IC to a larger interposer (which can be based on an organic molding compound as in the case of fan-out (FO) style substrate, and/or (b) a larger interposer (which can be based on silicon) to a larger laminate substrate in an extreme 2.5D IC will inevitably subject the corner flip chip bonded solder joints (and other weak points in the 2.5D structure), whether they be conventional copper pillar micro-bumps or solder bumps, to higher thermal-expansion-mismatch induced strains/stresses (versus the central joints), leading possible to pre-mature failures during the operation of the 2.5D IC. The situation will be exacerbated in the face of increasing processor powers (e.g., GPU power already at 1,200 W/chip) which are already exceptionally high over a small GPU chip area of around 3.3 cm×2.6 cm. What makes matter even more challenging is the escalating complexities of larger interposers and larger laminate substrates containing more fine-line/space (L/S) redistribution layers (RDL) the future has in store for the industry in order to cope with escalating AI demands. This renders the bonding yield and warpage control more difficult when bonding the larger die to the larger interposer and the larger interposer to the larger laminate substrate using conventional flip chip solder bonding based on yesteryears'short solder bumps involving, for instance, smaller ICs, smaller interposers and/or smaller laminate substrates.

### SUMMARY

In an embodiment, large glass-core substrates are earnestly being pursued as a better alternative to the large, higher-layer-count, far more complex laminates of the future. A glass substrate (and related package) as large as 240 mm×240 mm (which is beyond 12″-wafer scale) has been envisaged. Compared to laminate substrates, the advantages of glass substrates include large-panel manufacturability, ultra-high resistivity, flat and rigid over a large panel area, and adjustable CTE to match that of silicon (˜3 ppm/° C.; i.e., of ICs) or to go in between the CTE of silicon and that (˜15 ppm/° C.) of the laminate substrate for enhanced package reliability in operation. Some researchers and technologists anticipate easier realization of fewer-layer-count, finer-L/S RDLs using the glass-core substrates compared to their laminate counterparts. This being said, both the laminate substrates and glass-core substrates are not ideal for helping to dissipate the heat from the high-power processors due to their typically low thermal conductivities (TCs) of <5 W/m·K.

According to a first aspect of the present disclosure, a composite substrate containing thermally conductive materials is provided. The composite substrate includes a glass base, a first RDL, a second RDL and a thermal dissipation layer. The glass base has a first surface, a second surface opposite to the first surface and a through glass via (TGV) extending to the second surface from the first surface. The first RDL is disposed adjacent to the first surface of the glass base or the thermal dissipation layer. The second RDL is disposed adjacent to the second surface of the glass base. The thermal dissipation layer is disposed on the glass base, having a through thermal via (TTV) extending to the TGV.

In an embodiment, the first RDL is disposed on the thermal dissipation layer, and the second RDL is disposed on the glass base.

In an embodiment, the thermal dissipation layer has a thermal conductivity equal to or greater than that of glass.

In an embodiment, the thermal dissipation layer is made of a high-thermal-conductivity (HTC) material including diamond, AlN, SiC, BAs, a material or an alloy embedded with a HTC material, a metal, a clad metal or a combination thereof.

In an embodiment, the thermal dissipation layer has a CTE equal to or higher than that of glass.

In an embodiment, each of the first RDL and the second RDL includes a dielectric layer containing a through-hole (e.g., via) conductive layer and a trace-hole conductive layer. The dielectric layer is disposed over the glass base and contains a through-hole and a trace-hole connected with the through-hole, wherein the through-hole exposes and is electrically connected to the TGV a. The through-hole conductive layer is disposed within the through-hole. The trace-hole conductive layer is disposed within the trace-hole and connected with the through-hole conductive layer.

According to a second aspect of the present disclosure, a semiconductor device is provided. The semiconductor device includes a composite substrate, a semiconductor chip and a memory component. The composite substrate includes a glass base, a first RDL, a second RDL and a thermal dissipation layer. The glass base has a first surface, a second surface opposite to the first surface and a TGV extending to the second surface from the first surface. The first RDL is disposed adjacent to the first surface of the glass base. The second RDL is disposed adjacent to the second surface of the glass base. The thermal dissipation layer is disposed on the glass base and has a TTV extending to the TGV. The semiconductor chip is disposed on the composite substrate. The memory component is disposed on the composite substrate. The semiconductor chip and the memory component are disposed side-by-side or are stacked in a vertical direction on top of the composite substrate.

In an embodiment, the first RDL is disposed on the thermal dissipation layer, and the second RDL is disposed on the glass base.

In an embodiment, the thermal dissipation layer has a thermal conductivity equal to or higher than that of glass.

In an embodiment, the thermal dissipation layer is made of thermal-conductivity material including diamond, AlN, SiC, BAs, a material or an alloy embedded with a HTC material, a metal, a clad metal or a combination thereof.

In an embodiment, the thermal dissipation layer has a CTE equal to or higher than that of glass.

In an embodiment, each of the first RDL and the second RDL includes a dielectric layer, a through-hole conductive layer and a trace-hole conductive layer. The dielectric layer is disposed above the glass base and has a through-hole and a trace-hole connected with the through-hole.

In an embodiment, the semiconductor device further includes a printed circuit board and a plurality of stilt bumps. The plurality of stilt bumps are disposed between the printed circuit board and the composite substrate. Each stilt bumps can have a height as tall as 40 μm or taller.

According to a third aspect of the present disclosure, a manufacturing method is provided. The manufacturing method includes the following steps: forming a thermal dissipation layer on a first surface of a glass base; forming a TGV in the glass base, wherein the glass base has both the first surface and a second surface opposite to the first surface, and the TGV extends to the second surface from the first surface; forming a TTV in the thermal dissipation layer, wherein the TGV extends to the matching TGV; forming a first RDL adjacent to the thermal dissipation layer; and forming a second RDL adjacent to the second surface of the glass base.

In an embodiment, in forming the first RDL adjacent to the first surface of the glass base, the first RDL is disposed on the thermal dissipation layer, and in forming the second RDL adjacent to the second surface of the glass base, the second RDL is disposed on the glass base.

In an embodiment, in forming the thermal dissipation layer on the glass base, the thermal dissipation layer has a thermal conductivity equal to or greater than that of glass.

In an embodiment, in forming the thermal dissipation layer on the glass base, the thermal dissipation layer is made of thermal-conductivity material including diamond, AlN, SiC, BAs, a material or an alloy embedded with a HTC material, a metal, a clad metal or a combination thereof.

In an embodiment, the thermal dissipation layer has a CTE equal to or higher than that of glass.

In an embodiment, forming the first RDL adjacent to the first surface of the glass base includes: forming a dielectric layer above the glass base; forming a trace-hole in the dielectric layer; forming a through-hole in the dielectric layer, wherein the through-hole is connected with the trace-hole and exposes the thermal glass via; forming a through-hole conductive layer within the through-hole; and forming a trace-hole conductive layer within the trace-hole, wherein the trace-hole conductive layer is connected with the through-hole conductive layer.

In an embodiment, the step of forming the trace-hole in the dielectric layer and the step of forming the through-hole in the dielectric layer are performed by an excimer laser and/or DLT (Digital Lithography Technology, DLT) from Applied Materials, for example.

In an embodiment, after step of forming the trace-hole and the through-hole in the dielectric layer, the manufacturing method further includes: forming a seed layer on a sidewall of the trace-hole and a sidewall of the through-hole; and in the step of forming the through-hole conductive layer within the through-hole and the step of forming the trace-hole conductive layer within the trace-hole, the through-hole conductive layer and the trace-hole conductive layer are formed through the seed layer by plating.

The above and other aspects of the disclosure will become better understood with regard to the following detailed description of the non-limiting embodiment(s). The following description is made with reference to the accompanying drawings.

### BRIEF DESCRIPTION OF THE DRAWINGS

FIG. 1 illustrates a schematic diagram of a composite substrate containing thermally conductive material according to an embodiment of the disclosure;

FIG. 2 illustrates a schematic diagram of a composite substrate containing thermally conductive materials according to another embodiment of the disclosure;

FIG. 3 illustrates a schematic diagram of a structure of the first RDL in FIG. 1 according to another embodiment of the disclosure;

FIG. 4 illustrates a schematic diagram of a semiconductor device according to another embodiment of the disclosure;

FIG. 5 illustrates a schematic diagram of a semiconductor device according to another embodiment of the disclosure;

FIG. 6 illustrates a schematic diagram of a semiconductor device according to another embodiment of the disclosure;

FIG. 7 illustrates a schematic diagram of a semiconductor device according to another embodiment of the disclosure;

FIGS. 8A to 8E illustrate schematic diagrams of a manufacturing method of the composite substrate in FIG. 2 according to an embodiment;

FIGS. 9A to 9E illustrate schematic diagrams of a manufacturing method of the composite substrate in FIG. 1 according to an embodiment; and

FIGS. 10A to 10E illustrate schematic diagrams of a manufacturing method of the first RDL in FIG. 3 according to an embodiment.

### DETAILED DESCRIPTION

Several embodiments are disclosed below for elaborating the invention. Those embodiments are for the purpose of elaboration only, not for limiting the scope of protection of the invention. Besides, secondary elements are omitted in the following embodiments to highlight the technical features of the invention.

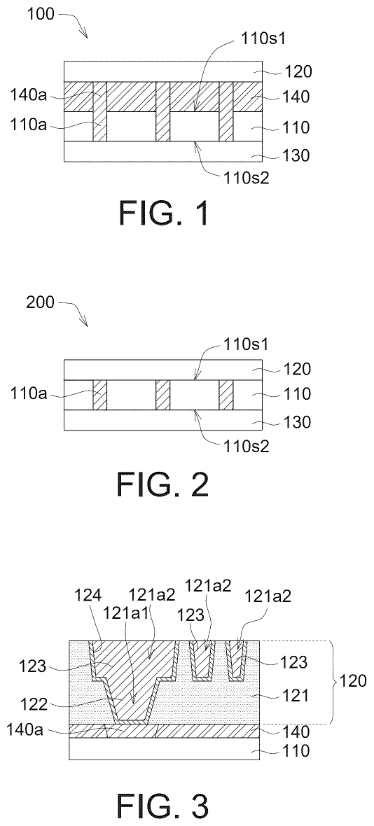

Referring to FIG. 1, which illustrates a schematic diagram of a composite substrate 100 containing a thermally conductive material according to an embodiment of the disclosure.

As illustrated in FIG. 1, the composite substrate 100 includes a glass base 110, a first RDL (redistribution layers) 120, a second RDL 130 and a thermal dissipation layer 140. The glass base 110 has a first surface 110s1, a second surface 110s2 opposite to the first surface 110s1 and at least one TGV 110a extending to the second surface 110s2 from the first surface 110s1. The first RDL 120 is disposed adjacent to the first surface 110s1 of the glass base 110. The second RDL 130 is disposed adjacent to the second surface 110s2 of the glass base 110. The thermal dissipation layer 140 is disposed on the glass base 110 and has at least one TTV 140a extending to the TGV 110a. As a result, the first RDL 120 and the second RDL 130 may be electrically connected through the TGV 110a and the TTV 140a.

As illustrated in FIG. 1, the glass base 110 can be based on common silicate glasses (including fused silica), soda-lime glasses, borosilicate glasses, lead glasses, aluminosilicate glasses, glass ceramics, HTC crystal dispersed glasses, and non-silicate glasses (e.g., with MgO) formed using inorganic and organic material including metals, aluminates, phosphates, borates, etc. In an embodiment, the glass base 110 has a thermal conductivity less than around 2 W/m·K.

As illustrated in FIG. 1, in the present embodiment, the first RDL 120 may be directly disposed on the first surface 110s1 of the glass base 110, and the second RDL 130 may be directly disposed on the second surface 110s2 of the glass base 110. In another embodiment, the first RDL 120 may be indirectly disposed on the first surface 110s1 of the glass base 110 through a layer such as the thermal dissipation layer, and/or the second RDL 130 may be indirectly disposed on the second surface 110s2 of the glass base 110 through a similar layer.

As illustrated in FIG. 1, the thermal dissipation layer 140 is disposed on the glass base 110 and has at least one TTV 140a extending to the TGV 110a. As a result, the first RDL 120 and the second RDL 130 are electrically connected through the TGV 110a and the TTV 140a.

In an embodiment, the TTV 140a and the TGV 110a may be formed in the same manufacturing process, for example, lithography process, etching, etc. In another embodiment, the TGV 110a and the TTV 140a may be formed in two individual manufacturing processes (for example, lithography process, etching, etc.) respectively. In addition, the TGV 110a and the TTV 140a may completely overlap one another or partly overlap in a thickness direction of the composite substrate 100.

The thermal dissipation layer 140 has a good thermal conductivity (TC) which is equal to or greater than that of glass. For example, the thermal dissipation layer 140 may be made of a high-thermal-conductivity (HTC) material such as diamond, AlN, SiC, BAs, a material or an alloy embedded with a HTC material (e.g., diamond or SiC—metal alloys), a metal, a clad metal (e.g., Cu/Invar/Cu) or a combination thereof.

In addition, the thermal dissipation layer 140 has a coefficient of thermal expansion (CTE) which is comparable to that of glass. The thermal dissipation layer 140 can refer to a layer that combines a HTC layer with a LCTE (low-coefficient-of-thermal-expansion) layer, for example, a clad metal such as Cu/Invar/Cu (whose CTE ranges between 2 ppm/° C. and 7ppm/° C.), Cu/Mo/Cu, etc. In an embodiment, the thermal dissipation layer 140 may be made of a HTC material such as diamond, AlN, SiC, etc.

Referring to FIG. 2, FIG. 2 illustrates a schematic diagram of a composite substrate 200 containing thermally conductive materials according to another embodiment of the disclosure.

As illustrated in FIG. 2, the composite substrate 200 includes the glass base 110, the first RDL 120 and the second RDL 130. The composite substrate 200 includes the features the same as or similar to that of the composite substrate 100 with at least one difference being the composite substrate 200 may omit the thermal dissipation layer 140 and the first RDL 120 is thereby disposed on the first surface 110s1 of the glass base 110.

The glass base 110 has a first surface 110s1, a second surface 110s2 opposite to the first surface 110s1 and at least one TGV 110a extending to the second surface 110s2 from the first surface 110s1. The first RDL 120 is disposed adjacent to the first surface 110s1 of the glass base 110 while the second RDL 130 is disposed adjacent to the second surface 110s2 of the glass base 110. As a result, the first RDL 120 and the second RDL 130 are electrically connected through the TGV 110a.

In FIG. 1, the first RDL 120 is disposed on the thermal dissipation layer 140 which is deposited on the first surface 110s1 of the glass base 110 and contains at least one TTV 140a extending to the TGV 110a, while the second RDL 130 is disposed on the second surface 110s2 of the glass base 110. Take a 2.5D IC, for instance, the composite substrate 200 may take the place of the laminate substrate, the interposer or a heterogeneous substrate that integrates the interposer and the laminate substrate.

In another embodiment, though not shown, a composite substrate can be formed by bonding the composite substrate 200 in FIG. 2 containing the first RDL 120, the second RDL 130 and the TGVs 110a connecting the first RDL 120 and the second RDL 130 to a thermal dissipation layer 140 containing at least one RDL and TTVs. Bonding here can be achieved by copper hybrid bonding or flip chip solder bonding. In other embodiment, another thermal dissipation layer 140 may be disposed on the first RDL 120 in FIG. 2, and a third RDL (which includes the features the same as or similar to those of the first RDL 120 and/or the second RDL 130) may be disposed on such another thermal dissipation layer 140, wherein the first RDL 120 in FIG. 2 is located between the glass base 110 in FIG. 2 and such another thermal dissipation layer 140 in FIG. 1, and the bonding between such another thermal dissipation layer 140 and the first RDL 120 in FIG. 2 can be achieved by copper hybrid bonding or flip chip solder bonding.

Referring to FIG. 3, which illustrates a schematic diagram of a structure of the first RDL 120 in FIG. 1 according to another embodiment of the disclosure.

The through hole's conductive layer is disposed within the through hole, while the trace-hole's conductive layer is disposed within the trace-hole and connected with the through hole's conductive layer.

For example, as illustrated in FIG. 3, the first RDL 120 includes a dielectric layer 121, a through-hole conductive layer 122, a trace-hole conductive layer 123 and a seed layer 124. The dielectric layer 121 is disposed over the glass base 110 and has at least one through-hole 121a1 and at least one trace-hole 121a2 connected with the through-hole 121a1, wherein the through-hole 121a1 exposes the TTV 140a. The through-hole conductive layer 122 is disposed within the through-hole 121a1. The trace-hole conductive layer 123 is disposed within the trace-hole 121a2 and connected with the through-hole conductive layer 122. The seed layer 124 is formed on sidewalls of the through-hole 121a1 and sidewalls of the trace-hole 121a2. The through-hole conductive layer 122 and the trace-hole conductive layer 123 may be formed with the conductive through-hole 121a1 and the trace-hole 121a2 through the seed layer 124. The seed layer 124 may be made of copper (Cu), titanium, TiW, TaN, Cr, Ni or a combination thereof. The seed layer 124 may be a multi-layered structure, for example, a Ti/Cu layer.

The second RDL 130 includes the features the same as or similar to those of the first RDL 120, and they will not be repeated here.

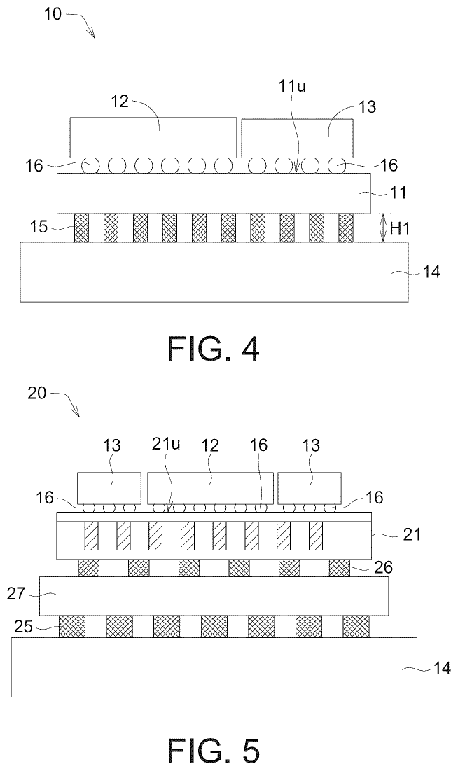

Referring to FIG. 4, which illustrates a schematic diagram of a semiconductor device 10 according to another embodiment of the disclosure. The semiconductor device 10 is, for example, a 2.5D IC stack, a 3D IC stack or a combination thereof.

As illustrated in FIG. 4, the semiconductor device 10 includes a composite substrate 11, at least one semiconductor chip 12, at least one memory component 13, a substrate 14, at least one first contact 15 and at least one second contact 16. The semiconductor chip 12 is disposed on the composite substrate 11. The memory component 13 is disposed on the composite substrate 11. The semiconductor chip 12 and the memory component 13 are disposed side-by-side or are stacked in a thickness direction (for example, a vertical direction) of the semiconductor device 10 on an upper surface 11u of the composite substrate 11.

As illustrated in FIG. 4, the composite substrate 11 includes the features the same as or similar to those of the composite substrate 100 or the composite substrate 200. Alternatively, the composite substrate 11 is the composite substrate 100 or the composite substrate 200.

In an embodiment, the semiconductor chip 12 is, for example, a processor such as a CPU (Central Processing Unit), a GPU (Graphics Processing Unit), a MPU (Micro-processor Unit) or a NPU (Neural Processing Unit), a FPGA (Field Programmable Gate Array), an I/O chip, a peripheral-function chip, a die-to-die interconnect or a co-packaged optics (CPO) consisting of a photonic IC (integrated circuit) and an electronic IC. In an embodiment, the memory component 13 is, for example, a HBM DRAM (High Bandwidth Memory).

As illustrated in FIG. 4, the substrate 14 is, for example, a laminate substrate, a printed circuit board (PCB) or combination thereof, the first contact 15 is, for example, a conductive tall bump (i.e., stilt bump), and the second contact 16 is, for example, a conductive bump, a conductive solder, a conductive pillar, etc. The stilt bump, the conductive bump, the conductive solder and/or the conductive pillar may be made of copper or an alloy, and a conductive solder such as tin (Sn) or an alloy thereof. The conductive bump is, for example, a copper pillar micro-bump.

The plurality of first contacts 15 are disposed between the substrate 14 and the composite substrate 11. The first contacts 15 (stilt bumps) are taller in comparison with the conventional shorter solder bumps which may be replaced by the first contacts 15. Although the ideal stilt bump height varies by application, each of at least one of the first contacts 15 has a height H1 as tall as 40 micrometers (μm) or even greater. A tall stilt bump can solve the problem of corner bump or joint failure during the operation of a large semiconductor device 10 involving a large composite substrate 11 and a large substrate 14 of dissimilar coefficients of thermal expansion (CTEs) and mechanical properties (e.g., moduli) where the corner joints correspond to large and the largest distances to the semiconductor device 10's neutral point. In FIG. 4, possible combinations of the composite substrate 11 and the substrate 14 include interposer and laminate substrate, laminate substrate and PCB, and interposer and laminate substrate/PCB composite.

As illustrated in FIG. 4, some second contacts 16 are disposed between the semiconductor chip 12 and the composite substrate 11 for electrically connecting the semiconductor chip 12 with the composite substrate 11, and some second contacts 16 are disposed between the memory component 13 and the composite substrate 11 for electrically connecting the memory component 13 with the composite substrate 11. The aforementioned features and attributes involving stilt bumps as described for the first contacts 15 also apply to the second contacts.

Referring to FIG. 5, which illustrates a schematic diagram of a semiconductor device 20 according to another embodiment of the disclosure. The semiconductor device 20 may include the structure the same as or similar to that of a CoWoS-S (based on Si interposer) device, a CoWoS-R (based on a RDL interposer) or a CoWoS-L (based on a fan-out interposer), which can contain embedded functions such as voltage regulators, capacitors, inductors, other passives, interconnect bridges with or without through-silicon vias (TSVs), or a combination of these CoWoS structures in 2.5D IC, 3D IC or 2.5D IC plus 3D IC configuration.

As illustrated in FIG. 5, the semiconductor device 20 includes a composite substrate 21, at least one semiconductor chip 12, at least one memory component 13, a substrate 14, at least one first contact 25, at least one second contact 16, at least one third contact 26 and another substrate 27. The semiconductor chip 12 is disposed on the composite substrate 21. The memory component 13 is disposed on the composite substrate 21. The semiconductor chip 12 and the memory component 13 are disposed side-by-side or are stacked in a thickness direction (for example, a vertical direction) of the semiconductor device 20 on an upper surface 21u of the composite substrate 21.

As illustrated in FIG. 5, the composite substrate 21 includes the features the same as or similar to those of the composite substrate 100 or the composite substrate 200. Alternatively, the composite substrate 21 is the composite substrate 100 or the composite substrate 200.

As illustrated in FIG. 5, the substrate 14 is, for example, a printed circuit board (PCB), the first contact 25 is, for example, a conductive bump, a conductive solder, a conductive pillar, a stilt bump, etc., the second contact 16 is, for example, a conductive bump, a conductive solder, a conductive pillar, a stilt bump, etc., and the third contact 26 is, for example, a conductive bump, a conductive solder, a conductive pillar, a stilt bump, etc. The first contact 25, the second contact 16 and the third contact 26 may involve different bonding structures and processes, or the same structures and processes.

As illustrated in FIG. 5, the plurality of first contacts 25 is disposed between the substrate 14 and the substrate 27 for electrically connecting the substrate 14 and the substrate 27. Some second contacts 16 are disposed between the semiconductor chip 12 and the composite substrate 21 for electrically connecting the semiconductor chip 12 with the composite substrate 21, and some second contacts 16 are disposed between the memory component 13 and the composite substrate 21 for electrically connecting the memory component 13 with the composite substrate 21. The plurality of third contacts 26 are disposed between the composite substrate 21 and the substrate 27 for electrically connecting the composite substrate 21 and the substrate 27.

In an embodiment, the substrate 27 is, for example, a CoWoS interposer, a laminate substrate, a glass substrate, a glass interposer, a glass-core substrate, a ceramic substrate or a metal substrate with or without embedded functions, for instance, voltage regulation circuitry, capacitors, inductors, interconnect bridges, die-to-die interconnect chips, I/O and peripheral-function chips, etc.

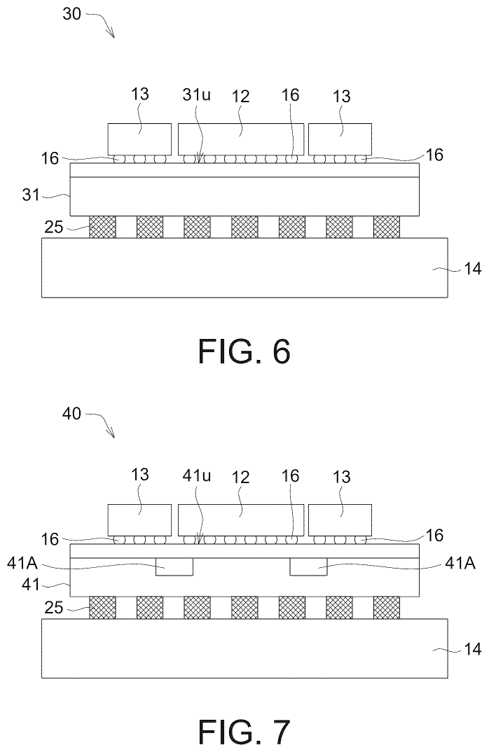

Referring to FIG. 6, which illustrates a schematic diagram of a semiconductor device 30 according to another embodiment of the disclosure. The semiconductor device 30 may include the structure the same as or similar to that of a CoWoS-S (based on Si interposer) device, a CoWoS-R (based on a RDL interposer) or a CoWoS-L (based on a fan-out interposer), which can contain embedded functions such as voltage regulators, capacitors, inductors, other passives, interconnect bridges with or without through-silicon vias (TSVs), or a combination of these CoWoS structures in 2.5D IC, 3D IC or 2.5D plus 3D configuration.

As illustrated in FIG. 6, the semiconductor device 30 includes a composite substrate 31, at least one semiconductor chip 12, at least one memory component 13, a substrate 14, at least one first contact 25 and at least one second contact 16. The semiconductor chip 12 is disposed on the composite substrate 31. The memory component 13 is disposed on the composite substrate 31. The semiconductor chip 12 and the memory component 13 are disposed side-by-side or are stacked in a thickness direction (for example, a vertical direction) of the semiconductor device 30 on an upper surface 31u of the composite substrate 31.

As illustrated in FIG. 6, the composite substrate 31 includes the features the same as or similar to those of the composite substrate 100 or the composite substrate 200. Alternatively, the composite substrate 31 is the composite substrate 100 or the composite substrate 200.

As illustrated in FIG. 6, the substrate 14 is, for example, a CoWoS interposer, a laminate substrate, a glass substrate, a glass interposer, a glass-core substrate, a ceramic substrate or a metal substrate with or without embedded functions, for instance, voltage regulation circuitry, capacitors, inductors, interconnect bridges, die-to-die interconnect chips, I/O and peripheral-function chips, etc. The first contact 25, the second contact 16 may involve different bonding structures and processes, or the same structures and processes.

As illustrated in FIG. 6, the plurality of first contacts 25 are disposed between the substrate 14 and the composite substrate 31 for electrically connecting the substrate 14 and the composite substrate 31. Some second contacts 16 are disposed between the semiconductor chip 12 and the composite substrate 31 for electrically connecting the semiconductor chip 12 with the composite substrate 31, and some second contacts 16 are disposed between the memory component 13 and the composite substrate 31 for electrically connecting the memory component 13 with the composite substrate 31.

Referring to FIG. 7, which illustrates a schematic diagram of a semiconductor device 40 according to an embodiment of the disclosure. The semiconductor device 40 may include the structure the same as or similar to that of a CoWoS-S (based on Si interposer) device, a CoWoS-R (based on a RDL interposer) or a CoWoS-L (based on a fan-out interposer), which can contain embedded functions such as voltage regulators, capacitors, inductors, other passives, interconnect bridges with or without through-silicon vias (TSVs), or a combination of these CoWoS structures in 2.5D IC, 3D IC or 2.5D plus 3D configuration.

As illustrated in FIG. 7, the semiconductor device 40 includes a composite substrate 41, at least one semiconductor chip 12, at least one memory component 13, a substrate 14, at least one first contact 25 and at least one second contact 16. The semiconductor chip 12 is disposed on the composite substrate 41. The memory component 13 is disposed on the composite substrate 41. The semiconductor chip 12 and the memory component 13 are disposed side-by-side or are stacked in a thickness direction (for example, a vertical direction) of the semiconductor device 40 on an upper surface 41u of the composite substrate 41.

As illustrated in FIG. 7, the composite substrate 41 includes the features the same as or similar to those of the composite substrate 100 or the composite substrate 200. Alternatively, the composite substrate 41 is the composite substrate 100 or the composite substrate 200. In an embodiment, compared to the composite substrate 31 in FIG. 6, the composite substrate 41 in FIG. 7 further includes at least one embedded component 41A, wherein the embedded component 41A is, for example, an embedded semiconductor component (for example, die, circuit, etc.), such as an active IC, a bridge die with or without through vias, a IVR (Integrated Voltage Regulator), a VRM (Voltage Regulation Module), a capacitor, an inductor, a die-to-die interconnect, an optical I/O, etc.

As illustrated in FIG. 7, the substrate 14 is, for example, a CoWoS interposer, a laminate substrate, a glass substrate, a glass interposer, a glass-core substrate, a ceramic substrate or a metal substrate with or without embedded functions, for instance, voltage regulation circuitry, capacitors, inductors, interconnect bridges, die-to-die interconnect chips, I/O and peripheral-function chips, etc. The first contact 25 and the second contact 16 may involve different bonding structures and processes, or the same structures and processes As illustrated in FIG. 7, the plurality of first contacts 25 is disposed between the substrate 14 and the composite substrate 41 for electrically connecting the substrate 14 and the composite substrate 41. Some second contacts 16 are disposed between the semiconductor chip 12 and the composite substrate 41 for electrically connecting the semiconductor chip 12 with the composite substrate 41, and some second contacts 16 are disposed between the memory component 13 and the composite substrate 41 for electrically connecting the memory component 13 with the composite substrate 41.

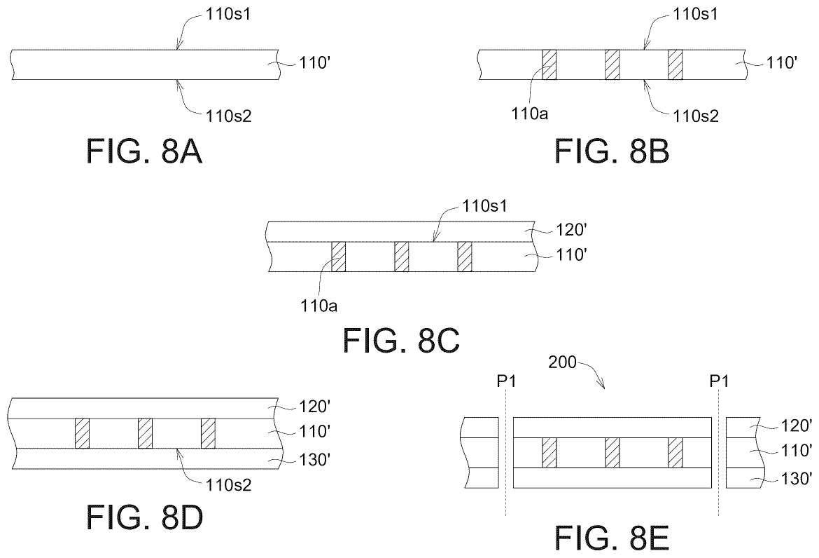

Referring to FIGS. 8A to 8E, which illustrate schematic diagrams of a manufacturing method of the composite substrate 200 in FIG. 2 according to an embodiment.

As illustrated in FIG. 8A, a glass base 110′ (which has not been singulated) is provided. The glass base 110′ has the first surface 110s1 and the second surface 110s2 opposite to the first surface 110s1.

As illustrated in FIG. 8B, at least one TGV 110a is formed in the glass base 110′. The TGV 110a extends to the second surface 110s2 from the first surface 110s1 by using, for example, deposition, lithography, etching, plating, planarization (by, for example, Chemical Mechanical Planarization, CMP), etc. For example, at least one through-hole is formed in the glass base 110′ by using, for example, a LIDE (Laser Induced Deep Etching), etc., and then a seed layer (for example, Ti/Cu layer) is formed on sidewall of the through-hole by using, for example, deposition, etc., and then a conductive material (for example, copper) is formed in the through hole through the seed layer to form the TGV 110a by using, for example, plating, etc. In addition, high-aspect-ratio TGVs may be created by, for example, LIDE, etc. In addition, the through-metal via in the event a metallic thermal dissipation layer is used may be achieved by using, for example, a focused electrical discharge method (FEDM) which, by the way, can also be used to create the TGVs. Besides LIDE, a 193-nm excimer laser (Coherent), femtosecond laser and/or a 1030 nanometers (nm) pico-second laser may also be used to create the TGV holes which may be fully filled with Cu or other suitable high-electrical-conductivity metals (e.g., W), or may be partially filled with an electrical conductor (e.g., Cu) and a filler (sometimes referred to as conformal vias; not shown), each of which forming conductive paths connecting the RDLs on both sides of the substrate.

As illustrated in FIG. 8C, a first RDL 120′ is formed on the first surface 110s1 of the glass base 110′ by using, for example, deposition, lithography, etching, planarization (for example, CMP), etc. The RDL may be based on dielectric/Cu including ABF/Cu (for line/space (L/S)¿10 μm), polyimide/Cu (L/S ≤5/5 μm) or oxide/Cu (L/S≤1 μm or even less) depending on the L/S requirements. In addition, ultra-fine-L/S RDLs may be created by using, for example, a combination of Applied Materials'Digital Lithography Technology (DLT), dual damascene and direct excimer laser patterning.

As illustrated in FIG. 8D, a second RDL 130′ is formed on the second surface 110s2 of the glass base 110′ by using, for example, deposition, lithography, etching, planarization (for example, CMP), etc.

As illustrated in FIG. 8E, at least one singulation path P1 passing through the first RDL 120′, the glass base 110′ and the second RDL 130′ is deployed using a combination of mechanical dicing, laser dicing, stealth laser cutting and plasma dicing to form at least one composite substrate 100 without the thermal dissipation layer (FIG. 2). In another embodiment, the structure in FIG. 8D may not be singulated.

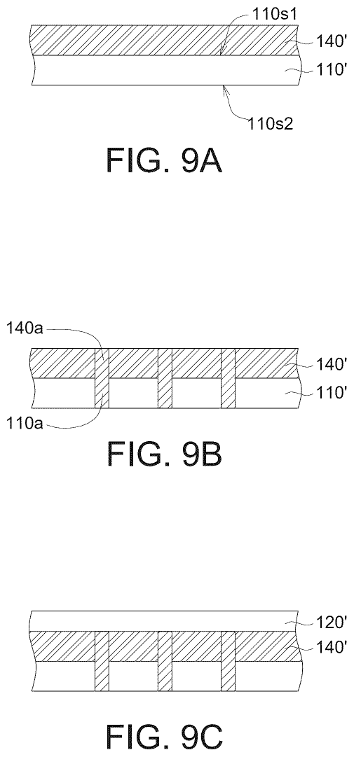

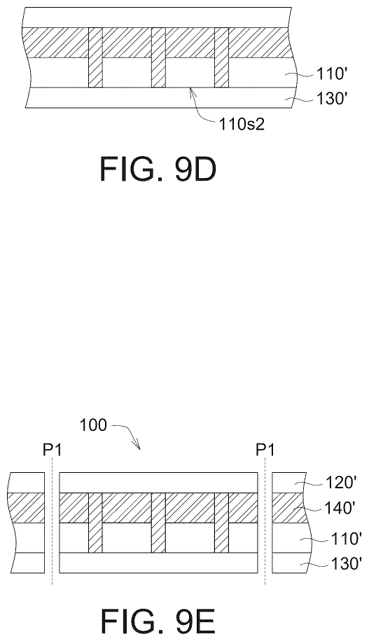

Referring to FIGS. 9A to 9E, which illustrate schematic diagrams of a manufacturing method of the composite substrate 100 in FIG. 1 according to an embodiment.

As illustrated in FIG. 9A, the glass base 110′ (which has not been singulated) is provided. The glass base 110′ has the first surface 110s1 and the second surface 110s2 opposite to the first surface 110s1. Then, a thermal dissipation layer 140′ (which has not been singulated) is formed on the first surface 110s1 of the glass base 110′ by using, for example, deposition, planarization, etc.

In FIG. 9A, the thermal dissipation layer 140′ is bonded to the glass base 110′. Bonding of a HTC, LCTE layer such as a clad metal, for example Cu/Invar/Cu (whose CTE ranges between about 2 ppm/° C. and 7 ppm/° C.), or Cu/Mo/Cu, may be achieved, after bringing glass and Cu/Invar/Cu into atomic contact using, for example, anodic bonding for bonding glass to silicon and to metals including Cu, Al, Kovar, Mo, Ni, Invar, etc. Bonding of glass to other HTC, LCTE materials suitable for panel formation may be achieved with the help of bonding with a thin adhesion layer which may be metallic or non-metallic.

The glass base 110′ has a size of 240 millimeters×240 millimeters or larger, for example. The thermal dissipation layer 140′ (for example, diamond plate) is attached to the glass base 110′ with an adhesive layer (not illustrated), which can also be a combination of Au (gold) on the glass base 110′ and Au on the backside of diamond if diamond is used for the thermal dissipation layer 140′. Au here may also be replaced by Cu or a solder on both surfaces. Compression or reflow bonding can be used to achieve the bonding of the thermal dissipation layer to the glass base 110′ when a metal such as Au, Cu or a solder is used. Prior to gold or copper deposition and as needed, thin metallization based on titanium (Ti), tungsten (W) or chromium (Cr) which makes a chemical bond with diamond can also be deposited, followed by deposition of typically palladium (Pd) or platinum (Pt) as a diffusion barrier and finally copper or gold can be deposited to prepare the diamond for soldering, eutectic bonding. Annealing is optional and can be done on an as-needed basis. A typical Ti/Pt/Au metallization is 1,000 Å/1,000 Å/10,000 Å thick on diamond. This can also be applied to the glass base 110′ as needed.

To achieve high low-temperature direct bonding yield between diamond and silicon: (1) the front side (the side to be bonded to silicon) surface of the thermal dissipation layer 140′ (for example, diamond plate) may be pre-deposited as needed with a thin silicon or silicon oxide layer as an activation layer followed as needed by CMP (to control its RMS that is root mean square average surface roughness) to nm scale; (2) bonding surfaces are cleaned by fast atom beam (“FAB”) gun (using argon, Ar, neutral atom beam) or ion gun (using Ar ion) to remove the oxide film, for instance, on the wafer surface in vacuum and to create dangling bonds at the surfaces. FAB works well for Si/Si, Si/SiO₂, metals, compound semiconductors and single crystal oxides while ion gun is known to work for SiO₂/SiO₂, Glass, silicon nitride (Si₃N₄)/Si₃N₄, Si/Si, Si/SiO₂, metals, compound semiconductor, and single crystal oxide; (3) a vacuum of 10-6 Pa (pascal) is required during bonding to prevent re-adsorption to activated bonding surfaces above; and (4) surface roughness of ˜1 nm Ra (arithmetic mean surface roughness) is preferred for both diamond and silicon. This level of Ra is achievable by CMP for silicon, and by sacrificial SiO2 layer deposition, SiO₂ planarization by CMP and dry reactive ion etching (DRIE) for diamond.

The main challenges of the glass-core technology is at the levels of TGV formation and metallization for ultra-high I/O densities. To mitigate these issues, optically, one can coat a suitable polymer layer on both sides of the composite core or glass core panel prior to TGV hole opening wherein the polymer here serves as a buffer layer between surface metallization and the core, mitigates the metal adhesion problem, and reduces the impact (e.g., cracking) of laser on glass surface during laser ablation. With some modifications, the processes and structures disclosed herein for HPC, data centers and AI applications can also be applied to include RF functions and co-packaged optics (e.g., optical I/Os) with the inclusion of, for instance, optical through vias and optical waveguides in the RDLs.

As illustrated in FIG. 9B, at least one TGV 110a is formed in the glass base 110′ and at least one TTV 140a is formed in the thermal dissipation layer 140′ by using, for example, deposition, lithography, etching, plating, planarization (for example, CMP), etc. The one TGV 110a and the one TTV 140a can be formed in the same manufacturing process. The TGV 110a and the TTV 140a may completely overlap or partly overlap in a thickness direction of the composite substrate 100.

As illustrated in FIG. 9C, the first RDL 120′ is created on the thermal dissipation layer 140′ by using, for example, deposition, lithography, etching, planarization (for example, CMP), etc.

As illustrated in FIG. 9D, the second RDL 130′ is formed on the second surface 110s2 of the glass base 110′ by using, for example, deposition, lithography, etching, planarization (for example, CMP), etc.

As illustrated in FIG. 9E, at least one singulation path P1 passing through the first RDL 120′, the thermal dissipation layer 140′, the glass base 110′ and the second RDL 130′ is deployed to form at least one composite substrate 100 by using, a combination of mechanical dicing, laser dicing, stealth laser cutting and plasma dicing. Following singulating, the composite substrate 100 contains at least one glass base 110′, at least one thermal dissipation layer 140′, at least one first RDL 120′ and at least one second RDL 130′. In another embodiment, the structure in FIG. 9D may not be singulated.

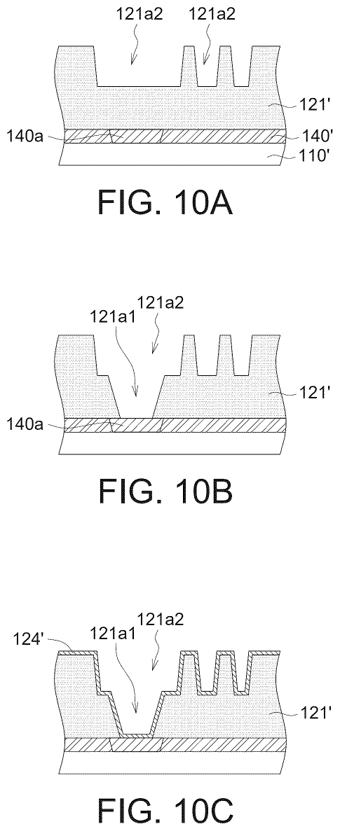

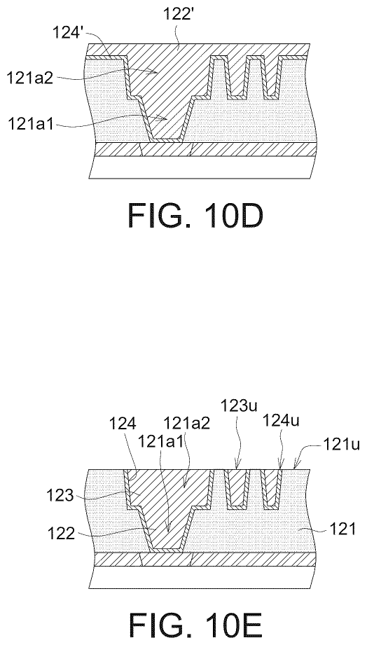

Referring to FIGS. 10A to 10E, which illustrate schematic diagrams of a manufacturing method of the first RDL 120 in FIG. 3 according to an embodiment.

As illustrated in FIG. 10A, a dielectric layer 121′ is formed above the glass base 110′ by using, for example, deposition, etc. Furthermore, the dielectric layer 121′ is formed on the thermal dissipation layer 140′ which is located above the glass base 110′. In addition, the thermal dissipation layer 140′ is formed between the glass base 110′ and the dielectric layer 121′. At least one TTV 140a is formed in the thermal dissipation layer 140′, and the dielectric layer 121′ covers the TTV 140a. Then, at least one trace-hole 121a2 is formed in the dielectric layer 121′ by using, for example, an excimer laser and/or DLT. The trace-hole 121a2 is not extended to the thermal dissipation layer 140′.

As illustrated in FIG. 10B, at least one through-hole 121a1 in the dielectric layer 121′ is formed by using, for example, an excimer laser and/or DLT, etc. The through-hole 121a1 extends to the TTV 140a and to the trace-hole 121a2.

As illustrated in FIG. 10C, a seed layer 124′ over the sidewalls of the through-hole 121a1 and the sidewalls of the trace-hole 121a2 is formed by using, deposition, etc. The seed layer 124′ may be made of copper, titanium, suitable metals such as TiW, TaN, Cr, Ni, etc. or a combination thereof. The seed layer 124′ may be a multi-layered structure, for example, a Ti/Cu layer.

As illustrated in FIG. 10D, a conductive layer 122′ is formed in the through-hole 121a1 and the trace-hole 121a1 through the seed layer 124′ by using, for example, plating, etc.

As illustrated in FIG. 10E, the conductive layer 122′ and the seed layer 124′ are planarized by using, for example, CMP. After CMP, the conductive layer 122′ forms at least one through-hole conductive layer 122 in the through-hole 121a1, at least one trace-hole conductive layer 123 in the trace-hole 121a1, and the seed layer 124′ forms the seed layer 124. After CMP, the dielectric layer 121 forms an upper surface 121u, the seed layer 124 forms an upper surface 124u, and the trace-hole conductive layer 123 forms an upper surface 123u, wherein the upper surface 121u, the upper surface 124u and the upper surface 123u are flushed with each other.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A composite substrate with thermally conductive material, comprising:
a glass base having a first surface, a second surface opposite to the first surface and a through glass via extending to the second surface from the first surface;
a first RDL (redistribution layer) disposed adjacent to the first surface of the glass base;
a second RDL disposed adjacent to the second surface of the glass base; and
a thermal dissipation layer disposed on the glass base and having a through thermal via extending to the through glass via.

2. The composite substrate according to claim 1, wherein the first RDL is disposed on the thermal dissipation layer, and the second RDL is disposed on the glass base.

3. The composite substrate according to claim 1, wherein the thermal dissipation layer has a thermal conductivity equal to or greater than that of glass.

4. The composite substrate according to claim 1, wherein the thermal dissipation layer is made of thermal-conductivity material comprising diamond, AlN, SiC, BAs, a material or an alloy embedded with a HTC material, a metal, a clad metal or a combination thereof.

5. The composite substrate according to claim 1, wherein the thermal dissipation layer has a Coefficient of Thermal Expansion (CTE) equal to or higher than that of glass.

6. The composite substrate according to claim 1, wherein each of the first RDL and the second RDL comprises:
a dielectric layer above the glass base and having a through-hole and a trace-hole connected with the through-hole, wherein the through-hole exposes the through thermal via;
a through-hole conductive layer within the through-hole; and
a trace-hole conductive layer within the trace-hole and connected with the through-hole conductive layer.

7. A semiconductor device, comprising:
a composite substrate, comprising:
a glass base having a first surface, a second surface opposite to the first surface and a through glass via extending to the second surface from the first surface;
a first RDL disposed adjacent to the first surface of the glass base;
a second RDL disposed adjacent to the second surface of the glass base; and
a thermal dissipation layer disposed on the glass base and having a through thermal via extending to the through glass via;
a semiconductor chip disposed on the composite substrate; and
a memory component disposed on the composite substrate;
wherein the semiconductor chip and the memory component are disposed side-by-side or are stacked in a vertical direction on top of the composite substrate.

8. The semiconductor device according to claim 7, wherein the first RDL is disposed on the thermal dissipation layer, and the second RDL is disposed on the glass base.

9. The semiconductor device according to claim 7, wherein the thermal dissipation layer has a thermal conductivity which is equal to or greater than that of glass.

10. The semiconductor device according to claim 7, wherein the thermal dissipation layer has a CTE which is equal to or higher than that of glass.

11. The semiconductor device according to claim 7, wherein each of the first RDL and the second RDL comprises:
a dielectric layer above the glass base and having a through-hole and a trace-hole connected with the through-hole;
a through-hole conductive layer within the through-hole; and
a trace-hole conductive layer within the trace-hole and connected with the through-hole conductive layer.

12. The semiconductor device according to claim 7, further comprising:
a printed circuit board; and
a plurality of stilt bumps between the printed circuit board and the composite substrate;
wherein each stilt bump has a height as tall as 40μm or taller.

13. A manufacturing method for a composite substrate, comprising:
forming a thermal dissipation layer on a glass base
forming a through glass via in the glass base, wherein the glass base has a first surface and a second surface opposite to the first surface, and the through glass via extends to the second surface from the first surface;
forming a through thermal via in the thermal dissipation layer, wherein the through thermal via extends to the through glass via;
forming a first RDL adjacent to the first surface of the glass base; and
forming a second RDL adjacent to the second surface of the glass base.

14. The manufacturing method according to claim 13, wherein in forming the first RDL adjacent to the first surface of the glass base, the first RDL is disposed on the thermal dissipation layer, and in forming the second RDL adjacent to the second surface of the glass base, the second RDL is disposed on the glass base.

15. The manufacturing method according to claim 13, wherein in forming the thermal dissipation layer on the glass base, the thermal dissipation layer has a thermal conductivity which is equal to or greater than that of glass.

16. The manufacturing method according to claim 13, wherein in forming the thermal dissipation layer on the glass base, the thermal dissipation layer is made of diamond, AlN, SiC, BAs, a thermal-conductivity material embedded with thermal-conductivity fillers, a metal, a clad metal or a combination thereof.

17. The manufacturing method according to claim 13, wherein the thermal dissipation layer has a CTE which is equal to or higher than that of glass.

18. The manufacturing method according to claim 13, wherein forming the first RDL adjacent to the first surface of the glass base comprises:
forming a dielectric layer above the glass base;
forming a trace-hole in the dielectric layer;
forming a through-hole in the dielectric layer, wherein the through-hole is connected with the trace-hole and exposes the through thermal via;
forming a through-hole conductive layer within the through-hole; and
forming a trace-hole conductive layer within the trace-hole, wherein the trace-hole conductive layer is connected with the through-hole conductive layer.

19. The manufacturing method according to claim 18, wherein step of forming the trace-hole in the dielectric layer and step of forming the through-hole in the dielectric layer are performed by an excimer laser and/or DLT (Digital Lithography Technology, DLT).

20. The manufacturing method according to claim 18, wherein after step of
forming the through-hole in the dielectric layer, the manufacturing method further comprises:
forming a seed layer on a sidewall of the through-hole and a sidewall of the trace-hole; and
in step of forming the through-hole conductive layer within the through-hole and step of forming the trace-hole conductive layer within the trace-hole, the through-hole conductive layer and the trace-hole conductive layer are formed through the seed layer by plating.
